(19) United States
(12) Patent Application Publication
(10) Pub. No.: US 2007/0063644 A1
(43) Pub. Date: Mar. 22, 2007

(54) Selective deposition of charged material for display device, apparatus for such deposition and display device

(76) Inventor: Jong Yun Kim, Yongin-si (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/524,734

(22) Filed: Sep. 20, 2006

(30) Foreign Application Priority Data
Sep. 20, 2005 (KR) 10-2005-87431

(51) Int. Cl. H01J 1/62

(52) U.S. Cl. 313/506

(57) ABSTRACT

An apparatus for depositing a thin film capable of controlling separation of ionized organic material vapor by an electric field so that an organic material is deposited on a substrate and a method of depositing a thin film using the same are disclosed. The apparatus for depositing the thin film includes a vacuum chamber whose inside remains vacuous, a substrate holder for supporting a substrate on which a deposition material is to be deposited in the vacuum chamber, and a deposition source provided to face the substrate to accommodate, heat, and evaporate the deposition material. The deposition source includes an ionization device for ionizing the deposition material and electric field generating devices for separating the vapor of the ionized deposition material by an electric field. Therefore, it is possible to reduce the amount of use of the deposition material and to deposit the organic material on the substrate at high speed.

### CROSS-REFERENCE TO RELATED APPLICATIONS

This application claims the benefit of Korean Patent Application No. 2005-0087431, filed on Sep. 20, 2005, in the Korean Intellectual Property Office, the disclosure of which is incorporated herein by reference.

### BACKGROUND

1. Field of the Invention

The present invention relates to an apparatus for depositing a thin film and a method for depositing a thin film using the same, and more particularly, to an apparatus for depositing a thin film capable of controlling separation of vapor of ionized organic materials by an electric field and a method of depositing a thin film using the same.

2. Discussion of Related Technology

An organic light emitting display, among other displays, displays an image using an organic light emitting diode. An organic light emitting diode (OLED) generates light by the recombination of electrons and holes in an organic light emitting material. An OLED typically includes an organic light emitting material interposed between a cathode and an anode. Electrons and holes are provided through the cathode and the anode and recombine with each other to excite the light emitting material. The light emitting material, while being stabilized from the excited energy level, emits light of a specific wavelength. The organic light emitting display can be driven by a relatively low voltage and has advantages of a thin and light structure, a wide viewing angle and a high response speed.

In forming a layer of an organic light emitting material on an organic light emitting display, various deposition methods have been used. Examples of the methods include physical vapor deposition (PVD), ion plating, sputtering deposition, and chemical vapor deposition (CVD).

A conventional method of forming an organic thin film will be described in detail with reference to FIG. 1. FIG. 1 schematically illustrates a conventional deposition chamber for depositing a material on a substrate.

As shown in FIG. 1, fine metal masks (FMM) 13 for depositing R, G, and B organic materials 11 are mounted on a substrate 12. An organic material 11 is contained in a deposition source 10 supported by a mounting table 16. The organic material 11 is vaporized and moves upward onto the substrate 12. Because the substrate 12 is generally wider than the deposition source 10, the organic material 11 obliquely reaches portions of the substrate surface which are not directly above the deposition source 10, as shown in FIG. 1. The fine metal masks 11 have a certain thickness. Thus, some fine metal masks that are not directly above the deposition source block a portion of the organic material which travels in an oblique direction. Therefore, the organic material 11 is not deposited on portions of exposed substrate surface. This problem adverse affects reliability of the resulting device.

The above-described method generally provides high color purity. However, it is difficult to form a fine pattern of high precision due to transformation of FMMs. In addition, the method is not suitable for forming a large display. It also has been found difficult to align a substrate with R, G, and B FMMs. In addition, pixel defining layers may be damaged by the FMMs.

In forming an organic thin film, a lithographic method can also be used to pattern a deposited layer of an organic material. Typically, such an organic layer is patterned using a photoresist as a mask for etching. A lithographic method generally allows forming a fine pattern. However, the organic thin film may be damaged by a developing solution used for patterning the photoresist or an etchant for the organic materials. The photoresist may also adversely affect reliability and life of the film.

Alternatively, an inkjet printing method has been used to directly pattern an organic thin film. According to the inkjet method, an organic material is dissolved or dispersed in a solvent, and is discharged from an inkjet printing device onto a substrate. This inkjet process is relatively simple, but has a poor yield. In addition, a thickness of a resulting film is not uniform. Furthermore, the inkjet method is not easily applicable to a display of a large size.

Another method for forming an organic thin film is laser thermal transcription. This method, however, is not effective due to technical problems and complicated processes. In addition, this method is not suitable for mass production.

### SUMMARY OF CERTAIN INVENTIVE ASPECTS

One aspect of the invention provides a display device. The display device comprises: a substrate; an array of light emitting pixels formed on the substrate; and a plurality of partitions partitioning neighboring pixels and insulating between the neighboring pixels, the plurality of partitions comprising a first partition, a first partition comprising a conductive wiring buried therein and connected to another conductive wiring formed between the substrate and the array of the light emitting pixels.

In the display device, the first partition may further comprise a conductive layer. The array of light emitting pixels may comprise a plurality of first color emitting pixels and the device may further comprise a plurality of first conductive lines interconnecting the first color emitting pixels. The array of light emitting pixels may further comprise a plurality of second color emitting pixels, and the plurality of first conductive lines may be not directly in electrical contact with any of the plurality of second color emitting pixels.

The array of light emitting pixels may further comprise a plurality of second color emitting pixels and the device may further comprise a plurality of second conductive lines interconnecting the second color emitting pixels. In addition, the plurality of second conductive lines may be not directly in electrical contact with any of the plurality of first color emitting pixels.

The array of light emitting pixels may further comprise a plurality of second color emitting pixels and a plurality of third color emitting pixels. The device may further comprise a plurality of second conductive lines interconnecting the second color emitting pixels, and the device may further comprise a plurality of third conductive lines interconnecting the third color emitting pixels.

The plurality of first conductive lines may not directly contact any of the plurality of second and third color emitting pixels. The plurality of second conductive lines may not directly contact any of the plurality of first and third color emitting pixels. The plurality of third conductive lines may not directly contact any of the plurality of first and second color emitting pixels. The light emitting pixels may comprise an organic light emitting diode (OLED).

Another aspect of the invention provides a method of making a display device. The method comprises: providing a substrate and a partially fabricated array formed on the substrate, the partially fabricated array comprising a plurality of pixel regions, each pixel region may comprise an electrode; selecting a first group of pixel regions among the plurality of pixel regions; applying a first voltage with a first polarity to each electrode of the first group of the plurality of pixel regions; and selectively depositing a first charged material onto the first group of pixel regions, the first charged material having a second polarity opposite to the first polarity.

The method may further comprise applying a second voltage to each electrode of the plurality of pixel regions other than the first group of pixel regions. In addition, the first voltage is different from the second voltage. The second voltage may be a ground voltage. The second voltage may have the second polarity. The display device may comprise an organic light emitting display device.

The substrate may further comprise a plurality of partitions partitioning the plurality of pixel region and each partition may comprise an electrode. The method may further comprise applying a third voltage to the electrode of the plurality of partitions, and the third voltage may differ from the first voltage. The third voltage may be a ground voltage. The third voltage may have the second polarity. The electrode may be positioned at an end of each partition, which faces away from the substrate and the electrode may substantially cover the end of the partition. Each partition may comprise a conductive wiring connected to the electrode, and applying the third voltage to the electrode may be via the conductive wiring.

In the above method, selectively depositing may comprise evaporating the first charged material in a chamber where the partially fabricated array is located, while applying the first voltage to each electrode of the first group. Selectively depositing may comprise forming a light emitting layer configured to emit a single colored light. Selectively depositing may comprise forming one or more layers of an organic light emitting device consisting of a hole-injecting layer, a hole-transporting layer, a light emitting layer, an electron-transporting layer, an electron-injecting layer, and layers with two or more functions of the foregoing layers.

The method may further comprise: selecting a second group of pixel regions among the plurality of pixel region; applying a second voltage with a polarity to each electrode of the second group of the plurality of pixel regions; and selectively depositing a second charged material onto the first group of pixel regions, the second charged material having a polarity opposite to the polarity of the second voltage. The pixel regions of the second group may differ from the pixel regions of the first group.

Yet another aspect of the invention provides a display device made by the method described above. The device may comprise an organic light emitting device.

Yet another aspect of the invention provides a system for depositing a thin film. The system comprises: a first chamber; a first substrate holder configured to and hold a substrate within the first chamber, the first substrate holder comprising a plurality of electrodes, a first one of the electrodes is selectively connected to a voltage of a first polarity, a second one of the electrodes is selectively connected to a voltage a second polarity different from the first polarity, the substrate comprising a first conductive line configured to contact the first electrode and a second conductive line configured to contact the second electrode; and a first vaporizer configured to supply in the first chamber vapor of a charged material of a second polarity.

In the system, the substrate may further comprise a partially fabricated array, which may comprise a plurality of groups of pixel regions, and a first group of pixel regions may be electrically connected to the first conductive line. The system may further comprise a second chamber; a second substrate holder configured to and hold a substrate within the second chamber, the second substrate holder comprising a plurality of electrodes, a first one of the electrodes of the second substrate holder is selectively connected to a voltage of the second polarity, a second one of the electrodes is selectively connected to a supply of a voltage of the first polarity, wherein the first and electrodes of the second substrate holder are configured to contact the first and second conductive lines respectively; and a second vaporizer configured to supply in the second chamber vapor of a charged material of a second polarity.

Another aspect of the invention provides an apparatus for depositing a thin film capable of controlling separation of vapor of ionized organic materials by an electric field without using fine metal masks (FMM) when an organic thin film is formed on a substrate in order to realize full colors to deposit the organic materials on the substrate and a method of depositing a thin film using the same.

Yet another aspect of the invention provides an apparatus for depositing a thin film capable of monitoring a deposition result in a sub pixel and a method of depositing a thin film using the same. The apparatus for depositing a thin film comprises a vacuum chamber whose inside remains vacuous, a substrate holder for supporting a substrate on which a deposition material is to be deposited in the vacuum chamber, and a deposition source provided to face the substrate to accommodate, heat, and evaporate the deposition material. The deposition source comprises an ionization device for ionizing the deposition material and electric field generating devices for separating the vapor of the ionized deposition material by an electric field.

Another aspect of the invention provides a method of depositing a thin film. The method comprises the steps of providing a substrate holder on which a gate wiring line and at least one ground wiring lines are formed in a vacuum chamber, forming wiring lines for applying gate signals to sub pixels, respectively, and a ground wiring line on the substrate that faces the gate wiring line and the ground wiring lines of the substrate holder so that the wiring lines and the ground wiring line are mounted on the substrate holder, providing a deposition source that is provided to face the substrate and in which electric field generating devices are provided, the deposition source for accommodating a deposition material, heating the deposition source to evaporate the deposition material, ionizing the evaporated deposition material by an ionization device, applying a gate signal to at least one sub pixel on which the deposition material is to be deposited on the substrate mounted on the substrate holder, and applying a ground signal to sub pixels on which the deposition material is not deposited, and depositing the ionized deposition material on the sub pixel to which the gate signal of the substrate is applied by the electric field formed by the electric field generating devices.

### BRIEF DESCRIPTION OF THE DRAWINGS

Various aspects and advantages of the invention will become apparent and more readily appreciated from the following description, taken in conjunction with the accompanying drawings.

FIG. 1 schematically illustrates a conventional chamber for depositing a material on a substrate;

FIG. 2 schematically illustrates a chamber for depositing a material on a substrate according to one embodiment of the invention;

FIG. 3 is a plan view illustrating an embodiment of wiring lines formed on a substrate;

FIG. 4A-4C illustrate configurations of wiring lines of the substrate holder of the chamber of FIG. 2 used for depositing red, green, and blue deposition material, respectively;

FIG. 5 is a cross-section schematically illustrating a substrate structure according to an embodiment; and

FIG. 6 is a schematic cross-section illustrating an electric field formed adjacent the substrate and movement paths of a deposition material according to an embodiment.

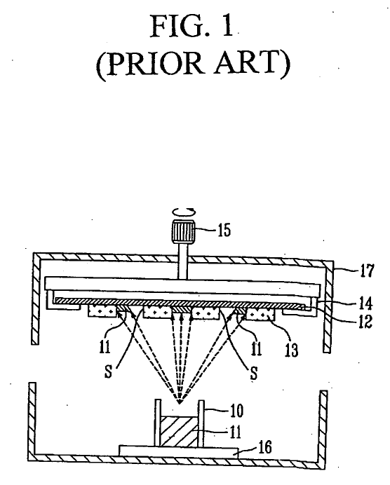

### DETAILED DESCRIPTION OF CERTAIN INVENTIVE EMBODIMENTS

A depositing system for depositing a thin film on a substrate according to embodiments of the invention will be described in detail with reference to the accompanying drawings. In the drawings, like reference numbers indicate identical or functionally similar elements.

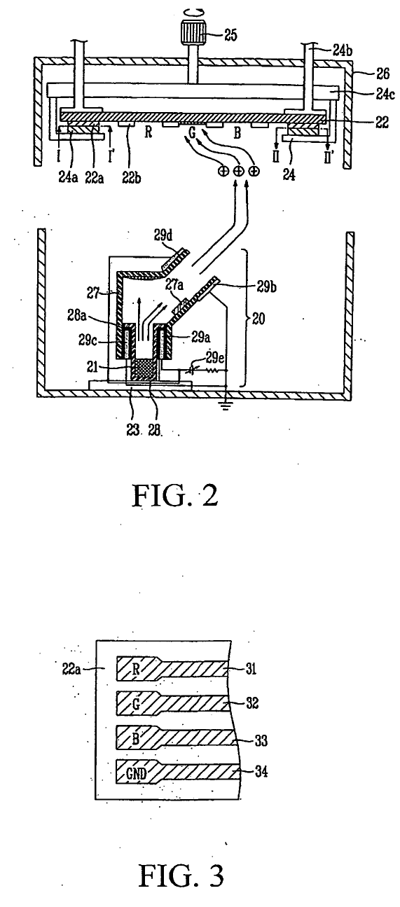

FIG. 2 schematically illustrates a deposition system for depositing a material on a substrate according to an embodiment. As shown in FIG. 2, the deposition system includes a vacuum chamber 26, a substrate holders 24, and a deposition source 20. The system also includes a rotating shaft 25 for rotating the substrate 22. The substrate holder 24 is configured to support the substrate 22. The deposition source 20 is configured to contain a deposition material 21 which will be deposited on the substrate 22. The deposition source 20 is also configured to heat the deposition material 21 to evaporate the deposition material 21. In addition, the deposition source 20 also includes electric field generating devices 29a-29e to selectively provide an ionized material. The deposition source 20 is positioned eccentric to the rotating shaft 25 to improve uniformity of a thin film deposited on the substrate 22. In addition, the deposition source 20 is supported by an additional mounting table 23.

The deposition source 20 includes a furnace made of metal or conductive ceramic. The furnace is heated by electronic beam or resistance heating to evaporate the deposition material. The deposition material is then sprayed through a nozzle of deposition source 20. The illustrated deposition source 20 includes a heater coil (not shown) for heating the deposition material 21. The deposition source 20 also includes an insulation plate 28a outside the furnace 28 so that the heat generated by the furnace 28 does not affect the deposition material 21.

The deposition source 20 also includes a cover 27 having an opening through which the deposition material 21 can be discharged. The cover is formed outside the insulation plate 28a. The electric field generating devices 29a, 29b, 29c, 29d, and 29e are provided on both ends of the furnace 28 and the cover 27.

Although not shown, the deposition source 20 further includes an ionization device for ionizing the deposition material 21. The ionization device includes a filament above the deposition source 20. A voltage is applied to the filament to ionize vapors of the deposition material 21 which pass the filament.

The cover 27 is configured to prevent unionized vapors from escaping outside. The cover 27 includes a ceiling directly over the furnace 28 so that unionized deposition material 21, while moving upward, can condensate on the ceiling of the cover 27 and drop back into the furnace 28. In this manner, unionized material can be collected and reused. The cover 27 is also configured to selectively discharge ionized material. The cover 27 includes a guide extending upward at about 45 degrees, as shown in FIG. 3 and an opening at an upper end of the guide. The guide includes electric field generating devices 29a and 29b. This configuration allows only ionized deposition material 21 to be discharged through the guide to the chamber.

The cover 27 may further include an electric field controlling device 27a on an inner surface of the guide. The electric field controlling device 27a is configured not to face the furnace 28, but is positioned close to the deposition source 20. The electric field controlling device 27a supplies charges with a polarity opposite to that of the ionized deposition material 21. The electric field controlling device 27a prevents the ionized deposition material 21 from colliding with the cover 27, and allows it to pass through the opening. The electric field controlling device 27a controls the kinetic energy of the deposition material 21, thus controlling the movement speed of the deposition material 21.

Although not illustrated, the deposition source 20 may further include a deposition ratio measuring monitor which is configured to monitor deposition thickness. For example, when the aperture ratio of a sub pixel is 50%, twice the thickness calculated by the deposition ratio measuring monitor is deposited in the sub pixel.

Referring back to FIG. 2, the substrate holder 24 also includes supporting table 24c which is connected to the substrate rotating means 25. The substrate holder 24 includes ribs at both ends which support the substrate 22. The substrate holder 24 also includes substrate positioning plates 24b which are connected to an external driver. The substrate positioning plates fix the substrate 22 on the ribs of while the holder 24 moves vertically.

In one embodiment, the substrate includes a plurality of wiring lines connected to pixels of the substrate. In addition, the substrate includes a ground wiring line connected to pixel partition regions. The substrate holder 24 includes a plurality of electrodes configured to provide a voltage to the wiring lines and the ground wiring line of the substrate. The plurality of electrodes are provided at one end of the substrate holder 24 and are in contact with the wiring lines and the ground wiring line of the substrate during a deposition process.

FIG. 3 illustrates one embodiment of wiring lines and a ground wiring line of a substrate, taken along the line I-I′ of FIG. 2. In the illustrated embodiment, Four wiring lines 31-34, including R, G, B, and ground wiring lines, are provided on the substrate. The wiring lines 31-33 are connected to R, G, and B sub pixels, respectively. The ground wiring line GND is connected to pixel partitions of the substrate.

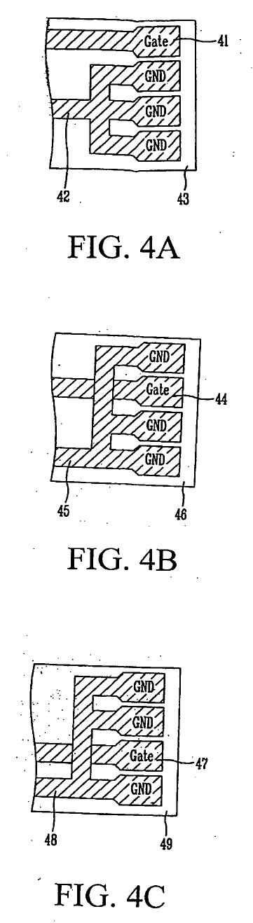

FIGS. 4A-4C illustrate various configurations of the electrodes of the substrate holder, taken along the line II-II′ of FIG. 2. The illustrated substrate holder includes an electrode for applying a gate signal and three ground electrodes for applying a ground voltage. The electrodes are configured to be in contact with the wiring lines and the ground wiring line of the substrate during operation of the deposition chamber.

FIG. 4A illustrates a configuration of the substrate holder electrodes for depositing a red deposition material. As shown in FIG. 4A, only the first electrode from the top is configured to apply a gate voltage to a wiring line of the substrate, which is the R wring line in the illustrated embodiment. The remaining three electrodes provides a ground voltage to the other wiring lines which are G, B, and ground wiring lines. As will be better understood from later description, this configuration allows only red pixels to be deposited with the red deposition material. Similarly, FIGS. 4B and 4C illustrate electrode configurations for depositing green and red deposition materials, respectively.

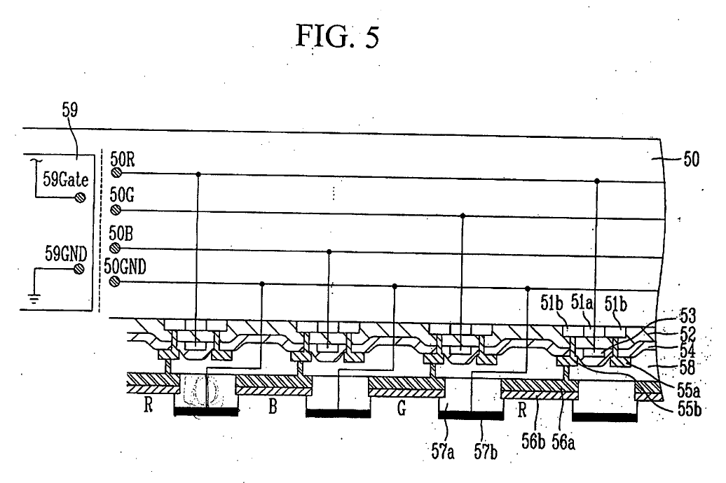

FIG. 5 is a sectional view schematically illustrating wiring lines configuration of a substrate according to an embodiment. In the embodiment, a gate voltage is provided from the substrate holder to green pixels when the G deposition material is deposited on the substrate.

The structure of the substrate 50 on which the deposition material is deposited is described. A buffer layer (not shown) is formed on the substrate 50. A semiconductor layer including an LDD layer (not shown) is formed between an active channel layer 51a and an ohmic contact layer 51b in a region of the buffer layer. A gate insulating layer 52 and gate electrodes 53 are patterned to be sequentially formed on the semiconductor layer. An interlayer insulating layer 54 is formed on the gate electrode 53 to expose the ohmic contact layer 51b in the semiconductor layer. Source and drain electrodes 55a and 55b are formed in a region of the interlayer insulating layer 54 to contact the exposed ohmic contact layer 51b.

Also, a polarization layer 58 is formed on the interlayer insulating layer 54 and via holes are formed on the planarization layer 58 to expose the source and drain electrodes 55a and 55b by etching a region of the planarization layer 58. The source and drain electrodes 55a and 55b and first electrode layers 56a and 56b are electrically connected to each other through the via holes. The first electrode layers 56a and 56b are formed in a region of the planarization layer 58 and pixel defining layers 57a in which apertures that at least partially expose the first electrode layers 56a and 56b are formed is formed on the planarization layer 58.

The lower first electrode layer 56a connected to the ohmic contact layer 51b operates as a reflecting layer. The upper first electrode layer 56b is formed of a material such as ITO and IZO.

A metal layer 57b is formed on the pixel defining layers 57a. The metal layer 57b operates as a buffer so that an electric field can be smoothly formed between the sub pixel G to which the gate signal is applied and the other sub pixels R and B. The metal layer 57b prevents a deposition material from being deposited. The metal layer 57b also operates as a black matrix layer for improving contrast. The metal layer 57b may be formed of Cr, Ag, or Al.

The method of depositing a thin film according to an embodiment is described with reference to FIG. 5. First, a substrate holder 59 which includes an electrode 59GATE and at least one ground wiring line 59GND is provided in a vacuum chamber. Then, a substrate having wiring lines 50R, 50G, and 50B for applying gate signals to pixels R, G, and B, respectively, and a ground wiring line 50GND is mounted on the substrate holder 59. The electrode 59GATE and the ground wiring line 59GND of the substrate holder 59 are in contact with the wiring lines 50R, 50G, and 50B and the ground wiring line 50GND during a deposition process.

Then, a deposition source is provided. The deposition source for accommodating the green (G) deposition material is positioned to face the substrate 50. Then, the G deposition material is evaporated by heating the deposition source and the evaporated G deposition material is ionized by an ionization device. Then, a gate voltage is applied to green pixels G on which the G deposition material is to be deposited. A ground signal is applied to the other pixels. The ionized deposition materials that move toward the substrate are affected by the electric field generated in the space between the substrate 50 and the deposition source.

Finally, the ionized G deposition material is deposited on the pixels G while the gate signal is applied to the pixels G. Because fine metal masks (FMM) are not used, it is possible to prevent a shadow phenomenon and to reduce the amount of use of the organic material.

According to the above embodiment, the G deposition material is deposited on the substrate. However, the R and B deposition materials can also be deposited in the same way except that a gate voltage is applied to a wiring line connected to R or B pixels.

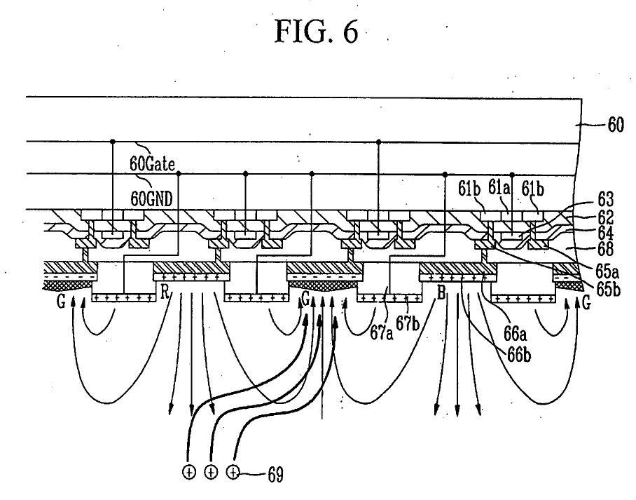

FIG. 6 is a schematic sectional view illustrating the electric field formed on the substrate and the movement paths of the deposition materials. Referring to FIG. 6, a gate signal is applied from the electrode of the substrate holder to the sub pixel G on which the G deposition material is deposited and a ground signal is applied to the other sub pixels R and G so that the G deposition material ionized to (+) charges is deposited only on the sub pixel G that has (−) charges. The ground signal is applied to the sub pixels R and G on which the G deposition material is not deposited so that the sub pixels R and G have the same (+) charges as the G deposition material. Therefore, the G material is not deposited on the sub pixels R and G. Also, the ground signal is applied to metal layer 67b formed on pixel defining layers 67a so that the metal layer 67b have the (+) charges. Therefore, the G deposition material is not deposited on the metal layer 67b. As a result, the G deposition material is deposited only on a desired sub pixel by the influence of the electric field.

The above-described embodiments employs an upward deposition apparatus. However, in other embodiments, a vertical deposition apparatus can be used.

According to the above embodiments, since the FMMs are not used when the organic thin film is formed on the substrate in order to realize full colors, it is possible to reduce the amount of use of organic materials and to prevent the shadow phenomenon from being generated by the FMMs. Also, it is not necessary to set an offset between the deposition source and the substrate.

Also, separation of the ionized organic material vapor is controlled by the electric field formed by the electric field generation devices formed on both ends of the deposition source and the electric field controlling device formed on the internal surface of the cover so that it is possible to deposit the organic material on the substrate at high speed.

Also, the deposition on the sub pixel is monitored so that it is possible to find defects of thin film transistors of the sub pixels on which the organic material is not deposited in advance.

Although various embodiments of the invention have been shown and described, it will be appreciated by those technologists in the art that changes might be made in these embodiments without departing from the principles and spirit of the invention, the scope of which is defined in the claims and their equivalents.

What is claimed is:

1. A display device, comprising:
a substrate;
an array of light emitting pixels formed over the substrate, wherein the array comprises at least one first color emitting pixel;
a plurality of partitions partitioning neighboring pixels and insulating between the neighboring pixels; and
a conductive line formed in a non-pixel region of the substrate, the conductive line comprising at least one gate signal applying wiring and a ground wiring.

2. The display device of claim 1 wherein the plurality of partitions comprises a first partition, the first partition comprising a conductive wiring therein, the conductive wiring being connected to another conductive wiring formed between the substrate and the array of the light emitting pixels.

3. The display device of claim 2, wherein the first partition further comprises a conductive layer electrically connected to the conductive wiring.

4. The display device of claim 3, wherein the conductive layer comprises at least one material selected from the group consisting of Cr, Ag, and Al.

5. The display device of claim, 1, wherein the light emitting pixels comprises an organic light emitting diode (OLED).

6. A method of making a display device, comprising:
providing a substrate and a partially fabricated array formed on the substrate, the partially fabricated array comprising a plurality of pixel regions, each pixel region comprising an electrode;
applying a first voltage with a first polarity to each electrode of a first group of pixel regions among the plurality of pixel regions; and
selectively depositing a first charged material onto the first group of pixel regions, the first charged material having a second polarity opposite to the first polarity.

7. The method of claim 6, further comprising applying a second voltage to each electrode of the plurality of pixel regions other than the first group of pixel regions, and wherein the first voltage is different from the second voltage.

8. The method of claim 7, wherein the second voltage is a ground voltage.

9. The method of claim 7, wherein the second voltage has the second polarity.

10. The method of claim 6, wherein the display device comprises an organic light emitting display device.

11. The method of claim 6, wherein the substrate further comprises a plurality of partitions partitioning the plurality of pixel regions, wherein each partition comprises an electrode, wherein the method further comprises applying a third voltage to the electrodes of the plurality of partitions, and wherein the third voltage differs from the first voltage.

12. The method of claim 11, wherein the third voltage is a ground voltage.

13. The method of claim 11, wherein the third voltage has the second polarity.

14. The method of claim 11, wherein the electrode is positioned at an end of each partition, which faces away from the substrate, and wherein the electrode substantially covers the end of the partition.

15. The method of claim 11, wherein each partition comprises a conductive wiring connected to the electrode, and wherein applying the third voltage to the electrode is via the conductive wiring.

16. The method of claim 6, wherein selectively depositing comprises evaporating the first charged material in a chamber where the partially fabricated array is located, while applying the first voltage to each electrode of the first group.

17. The method of claim 6, wherein selectively depositing comprises forming a light emitting layer configured to emit a single colored light.

18. The method of claim 6, wherein selectively depositing comprises forming one or more layers of an organic light emitting device consisting of a hole-injecting layer, a hole-transporting layer, a light emitting layer, an electron-transporting layer, an electron-injecting layer, and layers with two or more functions of the foregoing layers.

19. The method of claim 6, further comprising:
selecting a second group of pixel regions among the plurality of pixel region;
applying a second voltage with a polarity to each electrode of the second group of the plurality of pixel regions; and
selectively depositing a second charged material onto the first group of pixel regions, the second charged material having a polarity opposite to the polarity of the second voltage.

20. The method of claim 19, wherein the pixel regions of the second group differ from the pixel regions of the first group.

21. A display device made by the method of claim 6.

22. The device of claim 21, wherein the device comprises an organic light emitting device.

23. A system for depositing a thin film, comprising:
a first chamber;
a first substrate holder configured to hold a substrate within the first chamber, the first substrate holder comprising a plurality of electrodes, a first one of the electrodes being selectively connected to a voltage supply of a voltage of a first polarity, a second one of the electrodes being selectively connected to a voltage supply of a voltage of a second polarity different from the first polarity, the substrate comprising a first conductive line configured to contact the first electrode and a second conductive line configured to contact the second electrode; and
a first vaporizer configured to supply in the first chamber vapor of a charged material of a second polarity.

24. The system of claim 23, wherein the substrate further comprises a partially fabricated array, which comprises a plurality of groups of pixel regions, and wherein a first group of pixel regions is electrically connected to the first conductive line.

25. The system of claim 23, wherein the system further comprises
a second chamber;
a second substrate holder configured to hold a substrate within the second chamber, the second substrate holder comprising a plurality of electrodes, a first one of the electrodes of the second substrate holder being selectively connected to a voltage supply of a voltage of the second polarity, a second one of the electrodes being selectively connected to a voltage supply of a voltage of the first polarity, wherein the first and second electrodes of the second substrate holder are configured to contact the first and second conductive lines, respectively; and
a second vaporizer configured to supply in the second chamber vapor of a charged material of the second polarity.
